(19) United States
(12) Patent Application Publication
(10) Pub. No.: US 2003/0227306 A1
(43) Pub. Date: Dec. 11, 2003

(54) Low voltage Vcc detector

(76) Inventor: Ercole Rosario Di Iorio, Via Rietina (IT)

Correspondence Address: Leffert Jay & Polglaze, P.A., P. O. Box 581009, Minneapolis, MN, 55458-1009, US

(21) Appl. No.: 10/372,043

(22) Filed: Feb. 21, 2003

(30) Foreign Application Priority Data
Jun. 7, 2002 (IT) RM2002A000322

(51) Int. Cl. H03L 7/00

(52) U.S. Cl. 327/143

(57) ABSTRACT

A low voltage supply voltage detector uses a current comparator and transistors with mirrored currents to deassert a reset signal when the supply voltage reaches a programmable threshold voltage.

### RELATED APPLICATIONS

This application claims priority to Italian Patent Application Serial No. RM2002A000322, filed Jun. 7, 2002, entitled “LOW VOLTAGE VCC DETECTOR,” and which is incorporated herein by reference.

### FIELD

The present invention relates generally to low voltage detectors, and more specifically to an improved low voltage detector.

### BACKGROUND

Electronic circuits are contained in many devices, including by way of example only and not by way of limitation, integrated circuits, microchips, circuit boards, cellular telephones, computers, and the like, require power supplies of some sort. To start up such circuits, a reliable threshold voltage in the power supply must be met. Typical circuitry to measure the threshold voltages and to trigger a signal indicating that the threshold voltage has been reached are known as power on reset (POR) circuits.

POR circuits become increasingly important in low-voltage devices, such as in Flash memories, where supply voltages V_{cc} are typically in the range of 1.65 volts to 1.95 volts. There is the need, during a power on phase, to detect if the supply voltage (V_{cc}) has reached a certain threshold value, so that when the threshold value is reached, a reset signal can be deasserted.

Low voltage circuits cannot use traditional voltage threshold detectors, such as Zener diode detectors, since such circuits operate at higher voltages and consume a great deal of power compared to the power and voltages present in low voltage circuits.

In the past, the reset signal in lower voltage circuits has been obtained using bandgap circuits having a comparator, a resistive ladder, and a voltage reference, as is shown in U.S. Pat. No. 6,268,764, entitled BANDGAP VOLTAGE COMPARATOR USED AS A LOW VOLTAGE DETECTION CIRCUIT, issued Jul. 31, 2001 to Eagar et al. Such components require valuable silicon real estate and still consume a relatively large amount of power.

Further, in low voltage circuits, during power-on, the voltage reference grows with a slope similar to the supply voltage VCC slope. This can cause a false detection of the threshold voltage, thus resulting in the reset signal being deasserted too early.

For the reasons stated above, and for other reasons stated below which will become apparent to those skilled in the art upon reading and understanding the present specification, there is a need in the art for a smaller area threshold voltage detector, and a more reliable low voltage detector not relying on a voltage reference or voltage comparator.

### SUMMARY

The above-mentioned problems with supply voltage detectors and other problems are addressed by the embodiments of the present invention and will be understood by reading and studying the following specification.

In one embodiment, a method for operating a reset signal on a supply voltage includes providing the supply voltage to first and second transistors to generate first and second currents, and mirroring the first and the second currents with third and fourth transistors. The mirrored currents are compared with a current comparator, and the current comparator output is switched to deassert a reset signal through an inverter when the supply voltage reaches a predetermined threshold.

In another embodiment, a method for deasserting a reset signal includes maintaining a node voltage for an inverter input below the inverter voltage threshold until a supply voltage reaches a predetermined level, and deasserting the reset signal at the inverter output when the supply voltage reaches the predetermined level.

In still another embodiment, a method for indicating a predetermined threshold voltage condition for a supply voltage has been reached includes providing the supply voltage to a detection circuit, and drawing first and second currents through first and second distinct current paths in the circuit. The current paths have characteristics to cause the currents therein to move from a first current situation in which the first current is greater than the second current to a second situation in which the second current equals and exceeds the first current. The first and second currents are mirrored in third and fourth current paths in the circuit, and a reset signal is deasserted when the second current exceeds the first current.

In yet another embodiment, a method of detecting sufficiency of a ramped supply voltage includes providing the supply voltage to a detection circuit, and deasserting a detection circuit reset signal when the ramped supply voltage reaches a minimum voltage.

In another embodiment, a low voltage detector includes first and second transistors diode connected between a supply voltage and ground, first and second resistors connected in series with each other and in series with the first transistor, and a third resistor connected in series with the second transistor. Third and fourth transistors are connected to mirror current in the first and second transistors, a current comparator is connected between the supply voltage and the third and fourth transistors to compare the currents in the third and the fourth transistors, and an inverter has an input connected between the current comparator and the fourth transistor. The inverter generates a logic high signal until the voltage at its input exceeds a threshold voltage of the inverter.

In another embodiment, a circuit includes first, second, third, and fourth current paths between a supply voltage and ground, the third and fourth current paths mirroring current in the first and second current paths, a current comparator to compare the currents in the third and the fourth current paths, and an inverter having an input connected between the current converter and the fourth current path. The current comparator raises a voltage in the fourth current path above a threshold value of the inverter when the supply voltage reaches a predetermined level.

Other embodiments are described and claimed.

### BRIEF DESCRIPTION OF DRAWINGS

FIG. 1 is a circuit diagram of an embodiment of the present invention;

FIG. 2 is a diagram of a typical ramp voltage used in embodiments of the present invention;

FIG. 3 is a diagram of a reset signal generated by embodiments of the present invention; and

FIG. 4 is a timing diagram of the embodiment of FIG. 1.

### DETAILED DESCRIPTION

In the following detailed description of the embodiments, reference is made to the accompanying drawings, which form a part hereof, and in which is shown by way of illustration specific embodiments in which the inventions may be practiced. These embodiments are described in sufficient detail to enable those skilled in the art to practice the invention, and it is to be understood that other embodiments may be utilized and that logical, mechanical and electrical changes may be made without departing from the scope of the present invention. The following detailed description is, therefore, not to be taken in a limiting sense, and the scope of the present invention is defined only by the claims.

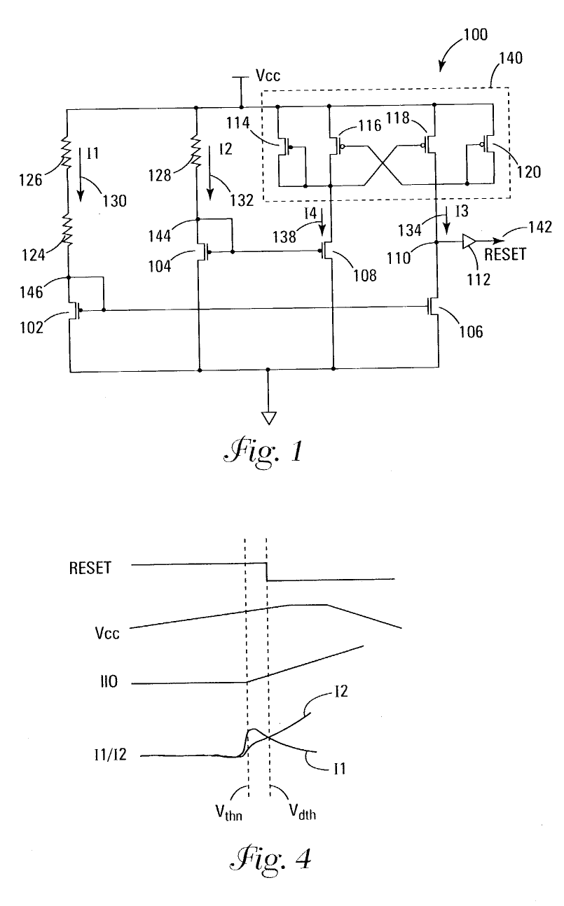

FIG. 1 is a circuit diagram of a low voltage V_{cc} detector 100 according to one embodiment of the present invention. V_{cc} detector 100 comprises a circuit connected between a supply voltage V_{cc} and ground. A first path between V_{cc} and ground comprises an n-channel transistor 102 diode connected in series with first and second resistors 124 and 126. A current I1, indicated by arrow 130, flows through this branch in operation. A second path between V_{cc} and ground contains another n-channel transistor 104 diode connected in series with resistor 128. A current I2, indicated by arrow 132, flows in the second path during operation.

The gate of transistor 102 is connected to the gate of transistor 106. Transistor 106 mirrors the current I1 in current path I3 indicated by arrow 134. The gate of transistor 104 is connected to the gate of transistor 108. Transistor 108 mirrors the current I2 in current path I4 indicated by arrow 138. The currents I3 and I4 are drawn through current comparator 140. Current comparator 140 comprises four p-channel transistors, connected as shown in FIG. 1 to compare currents I3 and I4. Current comparator 140 compares the currents I3 and I4. In this embodiment, in operation, when a ramping up supply voltage V_{cc} is supplied to the circuit, while current 13, which mirrors current I1, remains above current I4, which mirrors current I2, transistor 118 of current comparator 140 remains off and transistor 116 of current comparator 140 remains on. This keeps the voltage at node 110 below the threshold voltage of the inverter 112. Therefore, the reset signal 142, at the output of the inverter 112, remains at a logical high, that is, it is asserted. When the reset signal is asserted, a circuit or device connected to the reset signal 142 at the output of inverter 112 that requires a certain V_{cc} threshold to be met is not available for startup.

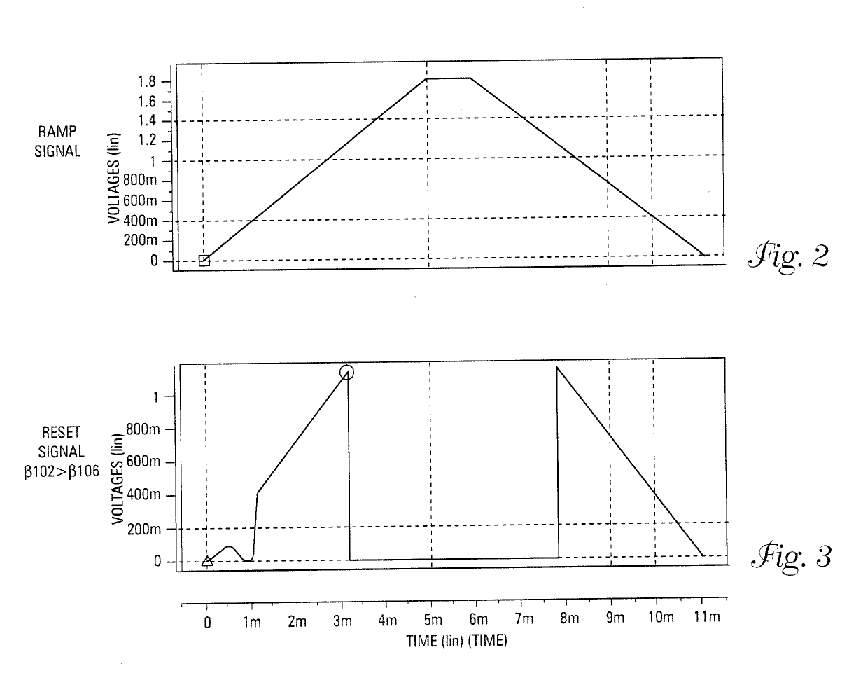

Inverter 112 is connected at node 110 to generate the reset signal. In operation, a power on sequence provides a voltage ramp to the supply (for example, a voltage ramp over 5 milliseconds) as is shown in FIG. 2 is applied to V_{cc}. When V_{cc} reaches the threshold voltage of an n-channel metal oxide semiconductor field effect transistor (MOSFET) (Vₜₕₙ) having characteristics similar to those of transistors 102 and 104, both MOSFETS 102 and 104 begin to conduct. In one embodiment the transistors are of different dimension. In this embodiment, W102/L102>W104/L104. When conduction begins in transistors 102 and 104, the current I1, indicated by arrow 130, is greater than the current I2, indicated by arrow 132, due to the characteristics of the transistors. Current I3, indicated by arrow 134, mirrored by transistor 106, is therefore initially greater than current I4, indicated by arrow 138, mirrored by transistor 108.

For this reason, until I1=I2 (and therefore I3=I4), the current comparator keeps the voltage at node 110 low since transistor 118 is off and transistor 116 is on. Therefore, the node voltage at node 110 stays lower than the threshold voltage of the inverter 112 (Vₜₕᵢₙᵥ), and the reset signal 142 at the output of inverter 112 remains high, or asserted. The current comparator 140, comprising in one embodiment p-channel transistors 114, 116, 118 and 120, does not flip, that is transistor 118 remains off, and transistor 116 remains on, and the reset signal stays at a logic high level, while current I3 is greater than current I4.

As V_{cc} continues to increase, in one embodiment according to the ramp shown in FIG. 2, the V_{cc} voltage increase reduces the gap between currents 11 and 12, because of a current limiting effect of resistor 124. At a certain point, indicated generally in the timing diagram of FIG. 4, as V_{cc} continues to increase, current I2 becomes greater than current I1. At this point, mirrored current I4 becomes greater than mirrored current I3, and the current comparator 140 flips. Transistor 116 turns off, and transistor 118 turns on. The node voltage at node 110 is raised to a point above that of the Vₜₕᵢₙᵥ of inverter 112, and the reset signal is deasserted, switching to a logical low level. At this point, the circuit has indicated that the V_{cc} level has reached the threshold level for startup of a device or circuit connected to the reset signal.

The V_{cc} value where I1=I2 represents the detector threshold voltage (V_{dth}), that is the voltage at which the circuit 100 deasserts the reset signal. In order to calculate V_{dth}, in one embodiment a hypothesis and certain conditions are presumed:

Hypothesis:

For transistors 106 and 102, W106/L106=W102/L102

For transistors 108 and 104, W108/L108=W104/L104

Conditions:

Transistors 102, 104, 106 and 108 are the same type (for example n-channel medium voltage MOSFETS)

For transistor 102, W102/L102=β*K

For transistor 104, W104/L104=β

Resistances 126 (R126)=128 (R128)=R

I1=I2=I (threshold condition)

Under previous conditions and hypothesis, it follows that:

V_{gs104}=V(N144)=V(N146)=R124*I+V_{gs102} [1]

since the equation of 102 and 104 in the saturation region are:

I1=K*β*[(V_{gs102}−Vₜₕₙ)²]/2

I2=β*[(V_{gs104}−Vₜₕₙ)²]/2

Solving for V_{gs102} and V_{gs104}, and substituting:

V_{thn+sqrt}(2I/β)=R124*I+V_{thn+sqrt}(2I/Kβ) [2]

Finally, solving for 1 in equation 2 yields:

I=I1=2*[(1−1/sqrt(K))²]/(R124²*β) [3]

When I1=I2=I:

V_{cc}=V_{dth}=V_{gs104}+R*I=Vₜₕₙ+sqrt(2*I/β)+R*I [4]

Substituting equation 3 into equation 4 results in:

V_{dth}=Vₜₕₙ+2*(1−1/sqrt(K))/(R124*β)+2*R*[(1−1/sqrt(K))²/R124²*β] [5]

Using this last equation 5, the V_{dth} of the detector 100 is calculable. The V_{dth} of the detector is also therefore settable by choosing the various values of the length and width of the transistors (the transistor P values) and the resistances R and R124. Also, in another embodiment, another degree of freedom in selection of V_{dth} is obtained by setting β102>β106 (W106/L106 for transistor 106) so that when I1=I2, the V_{cc} voltage is higher than in the condition I3=I4. This allows lowering V_{dth}. In one embodiment, V_{dth} is raised by setting β102<β106. A representative graph for the circuit 100 with β102>β106 is shown in FIG. 3 for the V_{cc} ramp of FIG. 2.

FIG. 4 is a timing diagram of the embodiment shown in FIG. 1. As can be seen with reference to FIGS. 1 and 2, on start of the ramp up in V_{cc}, the reset signal is high as the voltage at node 110 is low. When V_{cc} reaches the threshold voltages of transistors 102 and 104, they begin to conduct. As such, the currents conducted are mirrored in transistors 106 and 108 respectively. Because of the resistances in series with the transistors, initially, current I1 is higher than current I2. As V_{cc} continues to increase, the current limiting factor of resistor 124 limits the current I1 as current I2 continues to increase. At the threshold voltage of the detector 100, V_{dth}, current I2 becomes equal to current I1. At this point, the current I4 becomes larger than current 13. The current comparator flips, and the voltage at node 10 reaches a level in excess of the threshold voltage of the inverter 112. The reset signal therefore goes low, and the circuit indicates that V_{cc} is at a sufficient level for startup of any connected devices or other circuits.

In another embodiment, the circuit 100 is temperature compensated. That is, the threshold voltage result is temperature compensated. Such temperature compensation schemes are known in the art and are within the scope of the invention, but will not be described in further detail herein.

The embodiments of the present invention occupy a smaller area on silicon that previous solutions. The embodiments of the invention achieve the smaller area by elimination of the need for a startup circuit and startup sequence, a voltage reference, and a voltage comparator. Because of the elimination of those elements, a smaller area and less required power are achieved. Further, the minimum supply voltage required for the circuit embodiments is lower than in previous solutions.

By way of example only and not by way of limitation, advantages of the various embodiments of the present invention include low voltage supply operation (1.5-1.95 Volts), minor silicon area compared to other similar circuits, and elimination of components including a voltage reference and a voltage comparator.

### CONCLUSION

A low voltage supply voltage (V_{cc}) detector has been described. The low voltage V_{cc} detector draws current through a pair of transistors each having resistance in series therewith, and mirrors the currents to a second pair of transistors. The characteristics of the first pair of transistors and their series resistances results in currents that vary as supply voltage increases. When the supply voltage reaches a programmable threshold voltage, the current levels equal each other. At this point, a current comparator detects the cross in current level, and the voltage at a reset signal inverter is raised above the inverter threshold, and a reset signal which had been high is deasserted, indicating that the supply voltage has reached the threshold.

The V_{cc} detector of the present embodiments accomplishes the deassertion of the reset signal in a smaller silicon area and using fewer components than previous solutions.

It is to be understood that the above description is intended to be illustrative, and not restrictive. Although specific embodiments have been illustrated and described herein, it will be appreciated by those of ordinary skill in the art that any arrangement, which is calculated to achieve the same purpose, may be substituted for the specific embodiment shown. This application is intended to cover any adaptations or variations of the present invention. Therefore, it is manifestly intended that this invention be limited only by the claims and the equivalents thereof.

What is claimed:

1. A method for operating a reset signal on a supply voltage, comprising:
providing the supply voltage to first and second transistors to generate first and second currents therein;
mirroring the first and the second currents with third and fourth transistors;
comparing the mirrored currents with a current comparator; and
switching the current comparator output to deassert a reset signal when the supply voltage reaches a predetermined threshold.

2. The method of claim 1, wherein switching comprises:
raising a voltage level at a node connected to an inverter when the mirrored currents are equal.

3. The method of claim 1, and further comprising;
temperature compensating the predetermined threshold.

4. The method of claim 1, wherein the first and the third transistors are substantially identical.

5. The method of claim 1, wherein the second and the fourth transistors are substantially identical.

6. The method of claim 1, and further comprising:
modifying the predetermined threshold.

7. The method of claim 6, wherein modifying comprises:
varying a width to length characteristic of the first and third transistors to make the width to length characteristic of the first transistor larger than the width to length characteristic of the third transistor.

8. The method of claim 6, wherein modifying comprises:
varying a width to length characteristic of the first and third transistors to make the width to length characteristic of the first transistor smaller than the width to length characteristic of the third transistor.

9. A method for deasserting a reset signal, comprising:
maintaining a node voltage for an inverter input below the inverter voltage threshold until a supply voltage reaches a predetermined level; and
deasserting the reset signal at the inverter output when the supply voltage reaches the predetermined level.

10. The method of claim 9, wherein maintaining comprises:
drawing first and second currents through first and second current paths;
mirroring the first and the second currents through third and fourth current paths;
monitoring the third and the fourth currents; and
flipping a current comparator when the fourth current exceeds the third current, wherein flipping the current comparator raises the node voltage above the inverter voltage threshold.

11. The method of claim 10, wherein drawing first and second currents comprises placing first and second resistances in series with a first transistor in the first current path, and placing a third resistance in series with a second transistor in the second current path, and wherein the first and the second transistors have different characteristics.

12. A method for indicating a predetermined threshold voltage condition for a supply voltage has been reached, comprising:
providing the supply voltage to a detection circuit;
drawing first and second currents through first and second distinct current paths in the circuit, the current paths having characteristics to cause the currents therein to move from a first current situation in which the first current is greater than the second current to a second situation in which the second current equals and exceeds the first current;
mirroring the first and the second currents in third and fourth current paths in the circuit; and
deasserting a reset signal when the second current exceeds the first current.

13. The method of claim 12, wherein deasserting a reset signal comprises:
comparing the third and the fourth currents in a current comparator; and
raising a node voltage at an inverter connected between the current comparator and the fourth current path when the third current exceeds the fourth current.

14. The method of claim 12, and further comprising:
temperature compensating the predetermined threshold voltage condition.

15. The method of claim 12, and further comprising:
modifying the predetermined threshold voltage condition.

16. A method of detecting sufficiency of a ramped supply voltage, comprising:
providing the supply voltage to a detection circuit; and
deasserting a detection circuit reset signal when the ramped supply voltage reaches a minimum voltage.

17. The method of claim 16, wherein deasserting comprises:
providing the supply voltage ramp to first, second, third, and fourth current paths, the first and second current paths providing first and second currents that vary with supply voltage from an initial current differential in which the first current is less than the second current and a threshold current differential in which the second current equals the first current;
mirroring the first and the second currents in the third and the fourth current paths;
comparing the third and the fourth currents in a current comparator; and
raising a node voltage connected between the current comparator and the fourth current path when the fourth current equals the third current.

18. The method of claim 16, and further comprising:
modifying the minimum voltage by varying the first and the third current paths.

19. A circuit, comprising:
first, second, third, and fourth current paths between a supply voltage and ground, the third and fourth current paths mirroring current in the first and second current paths, respectively;
a current comparator to compare the currents in the third and the fourth current paths;
an inverter having an input connected between the current converter and the fourth current path;
wherein the current comparator raises a voltage in the fourth current path above a threshold value of the inverter when the supply voltage reaches a predetermined level.

20. The circuit of claim 19, wherein the first current path comprises:
a first and a second resistor connected in series with a first diode connected transistor.

21. The circuit of claim 19, wherein the second current path comprises:
a third resistor connected in series with a second diode connected transistor.

22. The circuit of claim 19, wherein the value of the first resistor and the value of the third resistor are equal.

23. The circuit of claim 19, wherein the third current path comprises a third transistor substantially identical to the first transistor.

24. The circuit of claim 21, wherein the width to length ratio of the first transistor differs from the width to length ratio of the third transistor.

25. The circuit of claim 21, wherein the width to length ratio of the first transistor is greater than the length to width characteristic of the third transistor

26. The circuit of claim 19, wherein the fourth current path comprises a fourth transistor substantially identical to the second transistor.

27. The circuit of claim 19, wherein:
the first current path comprises a first and a second resistor connected in series with a first diode connected transistor;
the second current path comprises a third resistor connected in series with a second diode connected transistor;
the third current path comprises a third transistor mirroring the current in the first transistor; and
the fourth current path comprises a fourth transistor mirroring the current in the second transistor.

28. The circuit of claim 27, wherein the first and the second transistors are of different length to width ratios.

29. The circuit of claim 27, wherein the first and the third transistors are substantially identical.

30. The circuit of claim 27, wherein the second and the fourth transistors are substantially identical.

31. The circuit of claim 27, wherein the first transistor has a length to width ratio greater than the length to width ratio of the third transistor.

32. The circuit of claim 27, wherein the first transistor has a length to width ratio smaller than the length to width ratio of the third transistor.

33. A low voltage detector, comprising:
first and second transistors each diode connected between a supply voltage and ground;
first and second resistors connected in series with each other and in series with the first transistor;
a third resistor connected in series with the second transistor;
third and fourth transistors mirroring current in the first and second transistors, respectively;
a current comparator connected between the supply voltage and the third and fourth transistors, the current comparator to compare the currents in the third and the fourth transistors; and
an inverter having an input connected between the current comparator and the fourth transistor, the inverter to generate a logic high signal until the voltage at its input exceeds a threshold voltage of the inverter.

34. The circuit of claim 33, wherein the first and the third transistors are substantially identical

35. The circuit of claim 33, wherein the second and the fourth transistors are substantially identical.
